(19) United States
(12) Patent Application Publication
(10) Pub. No.: US 2003/0006480 A1
(43) Pub. Date: Jan. 9, 2003

(54) MIMCap with high dielectric constant insulator

(76) Inventors: Jenny Lian, Walkill, NY (US); Xian J. Ning, Mohegan Lake, NY (US)

Correspondence Address: Ira S. Matsil, Suite 1000, 17950 Preston Rd., Dallas, TX, 75252-5793, US

(21) Appl. No.: 09/895,725

(22) Filed: Jun. 29, 2001

(51) Int. Cl. H01L 29/00

(52) U.S. Cl. 257/532

(57) ABSTRACT

A method of forming a metal-insulator-metal capacitor (see e.g., FIG. 1) in a back end of line structure comprises forming a metal bottom plate 16 in a first metalization layer 14, sputter depositing a high dielectric constant material 18 over the bottom plate 16, and forming a metal top plate 20 in a second metalization layer 22. The metal bottom plate 16 and metal top plate 22 are formed in consecutive metalization layers 14 and 22 in which interconnect structures 12 and 24 are also formed.

### TECHNICAL FIELD OF THE INVENTION

This invention relates to semiconductor processing, and more particularly to a MIMCap with a high dielectric constant insulator and method for forming the same.

### BACKGROUND OF THE INVENTION

The demand for metal-insulator-metal capacitors embedded in the integrated circuits has greatly increased. Metal-insulator-metal capacitors (MIMCap) have a capacitance defined as:

$$C = \frac{A}{d} {ϵ}_{o} {ϵ}_{r} , \qquad ( 1 )$$

where A is the area of the electrode, d is dielectric thickness, εₒ is the permittivity of free space and εᵣ is the relative permittivity, or dielectric constant, of the dielectric between the plates.

Generally, materials such as SiO₂, Si₃N₄, or some combination thereof are utilized as the dielectric material between the metal plates of the capacitor. Referring to Equation (1), capacitance can be increased by increasing the dielectric constant εₒ or by decreasing the dielectric thickness d. However, it is very difficult to achieve higher capacitance per unit area by lowering the dielectric thickness of these materials because the metal plates of the capacitor are not perfectly smooth. If the dielectric thickness is too thin, the capacitor plates will have high leakage and may result in electrical short. Thus, the adaptation of high permitivity dielectric materials would be helpful to achieving the goal of higher capacitances.

There are many high permitivity materials available. However, the processing of many of these materials requires high temperature. Since MIMCaps are usually built in the back-end-of-line (BEOL) structures, low temperature processing of dielectric materials at the BEOL is helpful in preventing damage to devices that have been built in the front-end-of-line or prior to the MIMCaps.

### SUMMARY OF THE INVENTION

These and other problems are generally solved or circumvented, and technical advantages are generally achieved, by the present invention that is a MIMCap having a high dielectric constant insulator and a method for producing the same.

In one aspect, the present invention provides a method of forming a metal-insulator-metal capacitor in a back-end-of-line structure. This process includes forming a metal bottom plate in a first metalization layer, sputter depositing a high dielectric constant material over the bottom plate, and forming a metal top plate in a second metalization layer. The metal bottom plate and metal top plate are formed in consecutive metalization layers in which interconnect structures are also formed.

The preferred embodiment process, or another process, can be used to form a novel semiconductor device that includes a capacitor. This device might include a first level interconnect formed in a metalization layer and a bottom plate formed in the same metalization layer as the first level interconnect. A first dielectric layer can be formed over the first level interconnect and a second dielectric layer formed over the bottom plate. In the preferred embodiment, the second dielectric layer would be formed from a material with a higher dielectric constant than the dielectric constant of the first dielectric layer. As examples, high-k dielectric materials such as SrTiO₃, Ta₂O₅, Al₂O₃, BTO, and/or BSTO can be used. A second level interconnect is formed in another metalization layer. A top plate is also formed in the same layer as the second level interconnect.

An advantage of a preferred embodiment of the present invention is that materials having a high dielectric constant can be processed at low temperatures in BEOL structures.

Another advantage of a preferred embodiment of the present invention is that two consecutive metal levels in BEOL can be used as the MIMCap bottom and top plates.

Yet another advantage of a preferred embodiment of the present invention is that shadow masking can be used to sputter deposit high dielectric constant materials resulting in process time and complexity savings.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the concepts and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The above features of the present invention will be more clearly understood from consideration of the following descriptions in connection with accompanying drawings in which:

FIG. 1 illustrates a preferred embodiment MIMCap structure of the present invention;

FIGS. 2A-2F illustrate cross-sectional views of a preferred embodiment method of the present invention;

FIGS. 3A-3F represent corresponding top views of the preferred embodiment method of the present invention as illustrated in FIGS. 2A-2F; and

FIG. 4 illustrates a preferred embodiment MIMCap of the present invention utilizing a cap layer.

Corresponding numerals and symbols in the different figures refer to corresponding parts unless otherwise indicated. The figures are drawn to clearly illustrate the relevant aspects of the preferred embodiments, and are not necessarily drawn to scale.

### DETAILED DESCRIPTION OF PREFERRED EMBODIMENTS

The making and using of the presently preferred embodiment is discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

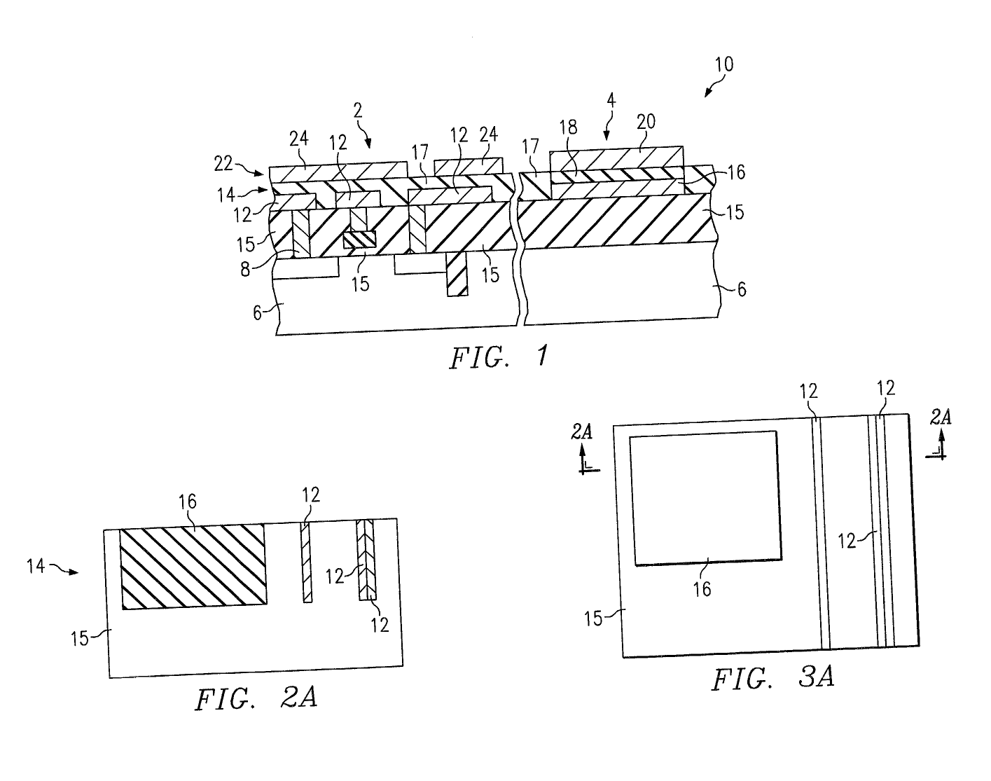

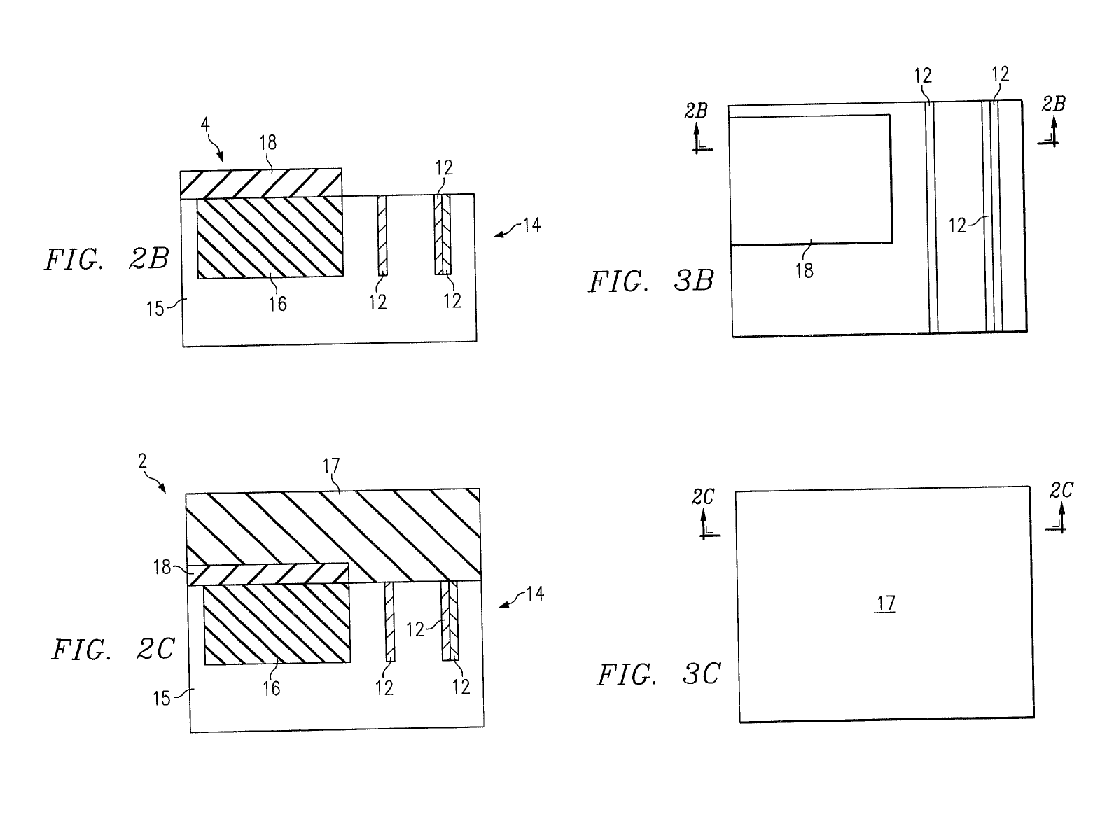

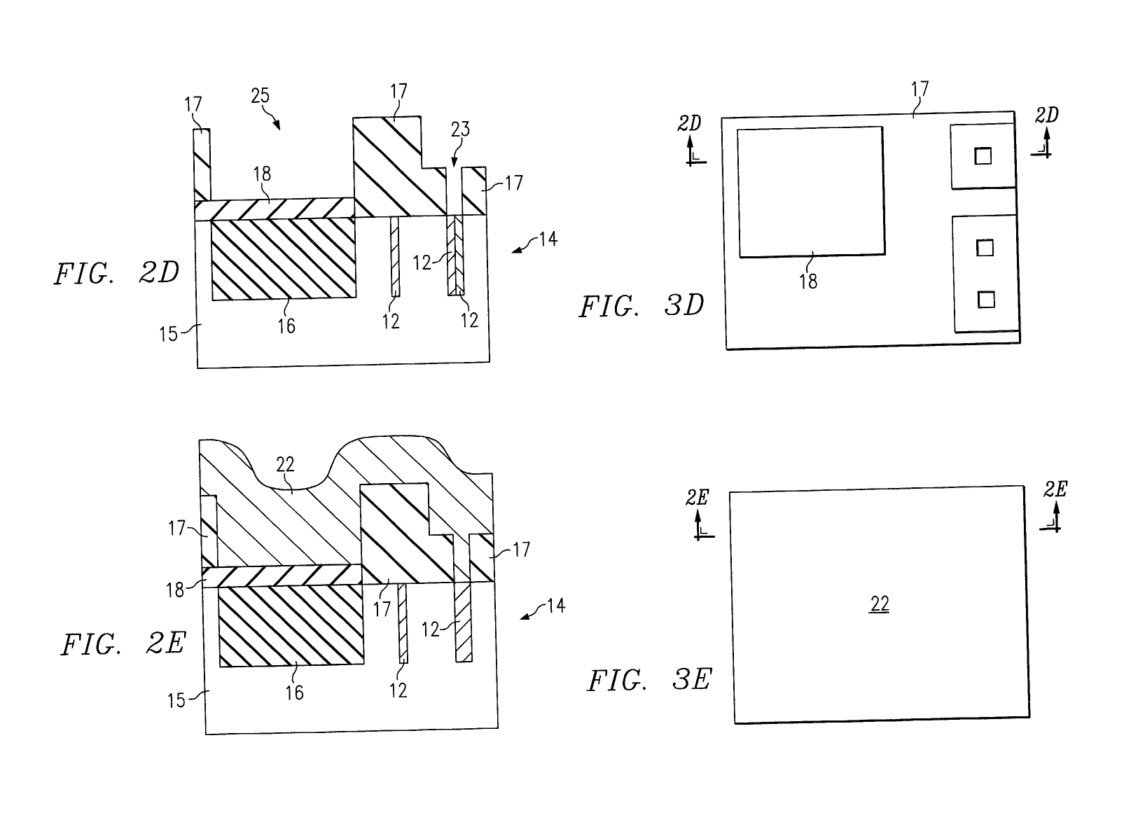

FIG. 1 illustrates a preferred embodiment device 10 that includes a capacitor 16/18/20 of the present invention. The preferred method of making a device of the invention will then be described with respect to FIGS. 2a-2f and 3a-3f.

Referring first to FIG. 1, the device 10 of FIG. 1 can be thought of as including two regions, an interconnect region 2 and a capacitor region 4. These regions are defined by the use of the metalization layers 14 and 22. Accordingly, in the interconnect region 2, the metalization layers 14 and 22 are used as interconnects (conductors that electrically couple components of the device 10). In the capacitor region 4, the metalization layers 14 and 22 are used to form a capacitor or capacitors.

The device 10 includes a number of circuits (illustrated by the MOS transistor 10) formed in a semiconductor region 6. In the preferred embodiment, the semiconductor region 6 comprises a silicon substrate. It is understood that the region 6 could also comprise a semiconductor layer formed over another region (e.g., an epitaxial layer or an SOI layer). While the active circuitry 8 is illustrated as being beneath the interconnect region 2, it is understood that this circuitry could also extend to the capacitor region 4. This feature could be easily accomplished, as an example, if the additional conductors (e.g., polysilicon and/or metal), which are not shown, are included between the metalization layer 14 and the devices 8. Insulating layer 15 separates the semiconductor region 6 (including devices 8 formed therein or thereon) from metalization layer 14.

Metalization layer 14 is illustrated at being the first metalization layer (sometimes referred to at Metal 1). It should be understood, however, that the layer 14 could be any (except the final) layer in the process. This metal layer 14 is used for at least two purposes. First, interconnects 12 are formed. These interconnects electrically coupled various components within the device. For purposes of illustration, three arbitrary interconnects 12 are shown.

Capacitor bottom plate 16 is also formed in first metal layer 14. While a single capacitor is shown in FIG. 1, it is understood that many capacitors can be formed.

Dielectric layer 18 is formed over the metal plate 16, as will be described in more detail below. This layer 18 will serve as the capacitor dielectric and, therefore, is formed from a high dielectric constant material. Examples of materials that can be used for layer 18 include SrTiO₃, Ta₂O₅, Al₂O₃, BaTiO₃ (BTO), (BaₓSr₁₋ₓ)TiO₃ (BSTO) and their compounds. These materials generally have a dielectric constant ranging from about 10 to about 400. This is considerably higher than conventional materials such as silicon oxide and silicon nitride that have dielectric constants of 4 and 7, respectively. The use of these and like high dielectric constant materials allows for increased capacitance due to the high dielectric constant.

Interlevel dielectric 17 is disposed over interconnect lines 12 and will serve to electrically insulate lines 12 from lines 22. Since it is desirable that the capacitance between the different level interconnect lines be minimized, ILD layer 17 preferably comprises a material with a lower dielectric constant than that of layer 18. In preferred embodiments, ILD 17 is an oxide layer or a nitride layer. In other embodiments, a low-k material such as silk could be used.

Second metal layer 22 is formed over the insulating layers 17 and 18. The layer 22 is preferably the next metal layer (after layer 14) formed in the process but other layers will suffice if removed from these areas. As with first layer 14, in the preferred embodiment, second metalization layer 22 is used for at least two purposes. Specifically, it will be used for interconnects 24 and for capacitor plate 20. In other embodiments, the metal layer 22 may be used only for capacitor plate 20.

The top and bottom plates 16, 20 and the first and second level interconnects 12, 24 can be comprised of any suitable conductor such as aluminum, titanium nitride, titanium, or a combination of these elements, as examples. The conductor can also be tungsten or copper. The metalization layer 14 can be formed from the same or different material as metalization layer 22.

In typical embodiments, the thickness of the dielectric layer 18 is in the range of about 50 nm to about 300 nm. The increased thickness of the dielectric layer 18 does not require the strict level of smoothness of the bottom and top plates 16, 20 that would be required by a conventional dielectric material that is made thin enough to get a comparable capacitance. In conventional MIMCaps, the bottom and top plates 16, 20 must be smooth in order to prevent leakage and shorting when a very thin dielectric layer is used. As shown by equation (1), an increase in the thickness d can be compensated for by when a higher dielectric constant εᵣ is used.

As another advantage, the process flow is simplified when the capacitor plates 16 and 20 are formed in existing metalization layers 14 and 22. By using the same metal layer for dual purposes, additional masking steps are eliminated.

A preferred embodiment of making a semiconductor device will now be described with references to FIGS. 2A-2F, which illustrate cross-sectional views a device during various stages of manufacture. FIGS. 3A-3F show the corresponding plan view.

A preferred method of forming a metal-insulator-metal capacitor (see FIG. 1) in a back-end-of-line structure comprises forming a metal bottom plate 16 in a first metalization layer 14, sputter depositing a high dielectric constant material 18 over the bottom plate 16, and forming a metal top plate 20 in a second metalization layer 22. The metal bottom plate 16 and metal top plate 22 are formed in consecutive metalization layers 14 and 22 in which interconnect structures 12 and 24 are also formed.

FIG. 2A shows the patterned first metalization layer 14. The formation of the metal bottom plate 16 can be performed by reactive ion etching of aluminum, copper or tungsten damascene, or dual-damascene levels. Using a damascene process, as an example, dielectric layer 15 is etched to form trenches in which the interconnects 12 and capacitor plate 16 will be formed. Metal 14 can then be deposited to fill the trenches. Excess material will be removed by chemical mechanical polish (CMP), as an example.

FIGS. 2B and 3B illustrate the next step in the method which includes the formation of capacitor dielectric layer 18. In the preferred embodiment, the dielectric layer 18 is formed by sputter depositing a high dielectric constant material, such as SrTiO₃, Ta₂O₅, Al₂O₃, BTO, BSTO or their compounds, in the capacitor region 4. This high dielectric constant material 18 can be sputter deposited using physical vapor deposition at temperatures less than 200 degrees Celsius. Because this step can be performed at relatively low temperatures, it is suitable for use in the BEOL MIMCAP structures. The dielectric material 18 is preferably deposited to a thickness in the range of about 50 nm to about 300 nm.

In one embodiment, a shadow mask is used to expose only the capacitor region(s) 4 on the wafer. The capacitor region 4 may actually comprise more than one region. In embodiments where a shadow mask is impractical, the high dielectric constant material 18 can deposited over the entire wafer and then lithographically patterned where the MIMCaps are located. The dielectric material 18 not patterned is then etched utilizing a wet etch or reactive ion etch, as examples. In some embodiments, an unpatterned layer of dielectric 18 can extend across multiple capacitors in a capacitor region 4.

In FIGS. 2C and 3C, inter-layer dielectric (ILD) material 17 is deposited over the first metal layer 14 and the dielectric material 18. The ILD material 17 provides the insulation between the metalization layers 14 and 22 in the interconnect region 2. In the preferred embodiment, ILD layer 17 is formed by plasma enhanced chemical vapor deposition (PECVD) of silicon dioxide. Other materials such as silicon nitride (e.g., Si3N4) or low-k materials such as silk can also be used. The layer 17 typically has a thickness in the range of about 100 nm to about 1000 nm.

FIGS. 2D (and 3D) illustrates the next step of an dual damascene process flow. Trenches 23 and 25 are formed in the dielectric material 17. These structures can be formed by lithography and ILD RIE that is selective to the capacitor dielectric layer 18. Alternatively, a timed etch can be used if the etchant is not selective to material 18. The pattern is determined by the desired shape of the capacitor plate 20 and interconnects 24. In a dual-damascene process, two etch steps are used. The step illustrated in FIG. 2D would be skipped in an RIE process.

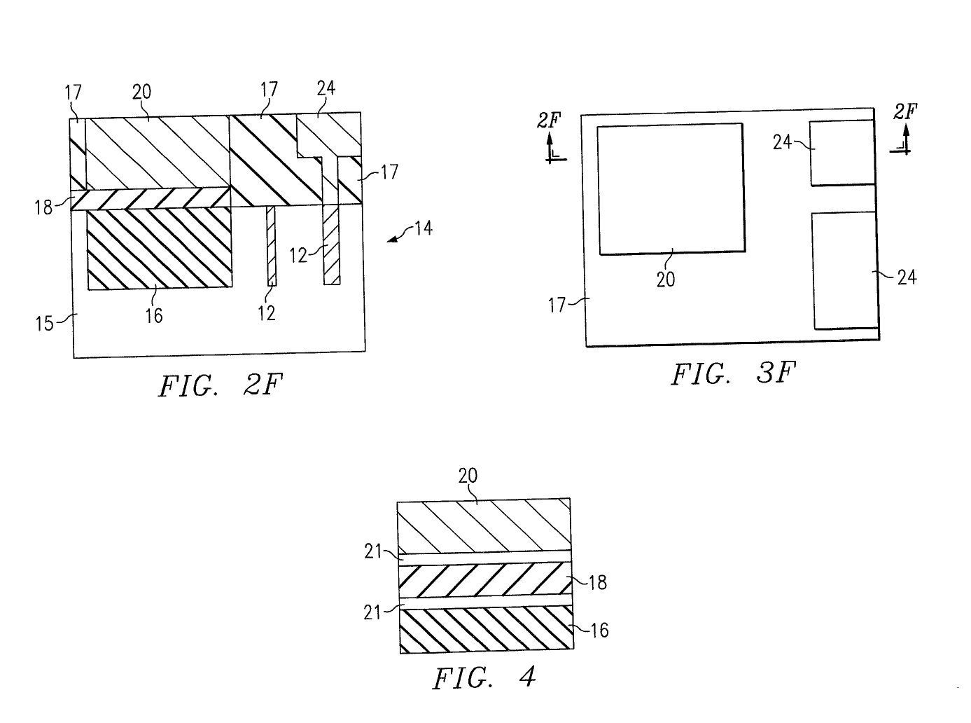

The metal 22 for the MIMCap top metal plate 20 and the second level interconnect 24 can then be deposited by physical vapor deposition, for example, as shown in FIGS. 2E and 3E. The metal 25 can be Al, TiN, Ti, and their combinations. In another embodiment, the metal 25 may be W or electroplated Cu that is deposited utilizing chemical vapor deposition. This embodiment may utilize a cap layer 21 (as shown in FIG. 4) between the metal plates 16 and/or 20 and the dielectric layer 18 to prevent the dielectric layer 18 from eroding the metal plates 16 and/or 20. The cap layer may comprise liner metals such as TaN, TiN, and Ta, which are deposited by physical vapor deposition, as an example. Also the cap layer may be comprised of TiN deposited by chemical vapor deposition.

FIGS. 2F and 3F illustrate the final patterning of the next (second) metalization layer 22. If the next metalization layer is a dual-damascene level, this step would be a chemical mechanical polish (CMP) of metal. If this is a metal RIE defined level, this step is a lithography and metal RIE.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a first level interconnect formed in a metalization layer;
a bottom plate formed in the same metalization layer as the first level interconnect;
a first dielectric layer formed over the first level interconnect;
a second dielectric layer formed over the bottom plate, the second dielectric layer comprising a material with a higher dielectric constant than the dielectric constant of the first dielectric layer;
a second level interconnect formed in another metalization layer; and
a top plate formed in the same layer as the second level interconnect;
wherein the top plate, the second dielectric layer, and the bottom plate form a capacitor.

2. The device of claim 1 wherein the dielectric level comprises a high permittivity material.

3. The device of claim 2 wherein the high permitivity material has a dielectric constant ranging from about 10 to about 400.

4. The device of claim 2 wherein the high permitivity material is selected from the group consisting of SrTiO₃, Ta₂O₅, Al₂O₃, BTO, BSTO, and combinations thereof.

5. The device of claim 2 wherein the dielectric layer is sputter deposited utilizing physical vapor deposition.

6. The device of claim 1 further comprising a cap layer positioned between the dielectric layer and one of the top and bottom plates .

7. A method of forming a metal-insulator-metal capacitor in a back end of line structure, the method comprising:
forming a metal bottom plate in a metalization layer;
depositing a high dielectric constant material over the bottom plate; and
forming a metal top plate in the next subsequent metalization layer
wherein the metal bottom plate and metal top plate are formed in consecutive metalization layers in which interconnect structures are also formed.

8. The method of claim 7 wherein at least one of the metal bottom plate or the metal top plate are formed by reactive ion etching aluminum.

9. The method of claim 7 wherein at least one of the metal bottom plate or the metal top plate comprises a copper layer formed using a damascene process.

10. The method of claim 7 wherein the depositing is sputter depositing.

11. The circuit of claim 10 wherein the high dielectric constant material is deposited at a temperature less than about 400 degrees Celsius.

12. The method of claim 7 wherein the high dielectric constant material has a thickness in the range of about 50 nm to about 300 nm.

13. The method of claim 7 and further comprising forming a cap layer between the dielectric material and the metal bottom plate.

14. The method of claim 13 wherein the cap layer is comprised of silicon nitride.

15. The method of claim 7 wherein the depositing of the high dielectric constant material comprises:
depositing a dielectric film on an entire wafer; and
patterning the capacitor regions utilizing lithography and etch.

16. The method of claim 15 wherein the etch is a wet etch.

17. The method of claim 15 wherein the etch is a reactive ion etch.

18. The method of claim 7 wherein the forming of the metal top and bottom plates is accomplished with physical vapor deposition.

19. The method of claim 7 wherein the high dielectric constant material is deposited with a shadow mask.

20. A method for forming a number of metal insulator metal capacitors on a semiconductor wafer, the method comprising:
forming a first metalization layer extending over an interconnect region and a capacitor region;
forming bottom capacitor plates in a first portion in the first metalization layer located in the capacitor region and simultaneously forming a first level of interconnects in a second portion of the first metalization layer located in the interconnect region;
using a shadow mask to physically vapor deposit a high dielectric constant material over the capacitor region such that the high dielectric constant material is not deposited over the interconnect region;
depositing a second metalization layer on the interconnect region and the capacitor region;
forming top capacitor plates by patterning a portion of the second metalization layer over the capacitor region and simultaneously forming a second level of interconnects by patterning a portion of the second metalization layer on the interconnect region.

21. The method of claim 20 and further comprising sputtering a cap layer between the high dielectric constant material and the top and bottom capacitor plates.

22. The method of claim 21 wherein the cap layer is comprised of silicon nitride.

23. The method of claim 20 further comprising forming an inter-layer dielectric in the interconnect region between the first metalization layer and the second metalization layer.
